(19) United States
(12) Patent Application Publication
(10) Pub. No.: US 2012/0013351 A1
(43) Pub. Date: Jan. 19, 2012

(54) METHOD FOR CONVERTING A SENSOR CAPACITANCE UNDER PARASITIC CAPACITANCE CONDITIONS AND A CAPACITANCE-TO-VOLTAGE CONVERTER CIRCUIT

(75) Inventors: Bernal Olivier Daniel, Singapore (SG); Minkyu Je, Singapore (SG); Andrew Kunil Choe, Singapore (SG); David Nuttman, Bnei-Brak (IL)

(73) Assignees: PHYSICAL LOGIC AG, Zug (CH); AGENCY FOR SCIENCE, TECHNOLOGY AND RESEARCH, Singapore (SG)

(21) Appl. No.: 13/119,766

(22) PCT Filed: Sep. 19, 2008
(86) PCT No.: PCT/SG2008/000358

§ 371 Date: Sep. 22, 2011

(51) Int. Cl. G01R 27/02

(52) U.S. Cl. 324/602

(57) ABSTRACT

A method for converting a sensor capacitance under parasitic capacitance conditions and a capacitance-to-voltage (CV) converter circuit for converting a sensor capacitance under parasitic capacitance conditions are provided. The method comprises the step of using a two stage operational amplifier (op-amp) in non-unity-gain configuration, wherein the two stage op-amp is chosen to be unstable in unity-gain configuration for reducing power consumption.

### FIELD OF INVENTION

The present invention relates broadly to a method for converting a sensor capacitance under parasitic capacitance conditions and to a capacitance-to-voltage converter circuit for converting a sensor capacitance under parasitic capacitance conditions.

### BACKGROUND

In applications that use a capacitive sensor element, capacitance-to-voltage (CV) converters are typically needed. Such applications include accelerometers, gyroscopes, pressure measurements systems, etc. Systems for such applications typically include either an external capacitive sensor that is outside an application specific integrated circuit (ASIC) that includes readout circuits, or an internal capacitive sensor embedded within the same chip of the ASIC with a readout circuit.

One challenge for current capacitive sensor interfaces is having a high impedance readout node and susceptibility of the node to parasitic and electromagnetic interferences. The readout of a capacitive sensor typically involves the conversion of the sensor capacitance or its changes to an electrical signal such as voltage, current or frequency. The design of the sensor is typically developed by considering the sensor and packaging specifications since both affect circuit performances. Typically, depending on the microelectromechanical systems (MEMS) and IC packaging (e.g. same die or not), the input parasitical capacitance of a readout IC can be high in relation to the sensing capacitor itself (e.g. more than 10 times). As a consequence, the readout circuit topology is typically chosen accordingly from the following groups. There are three main different groups currently: an AC-bridge with a voltage amplifier (continuous-time voltage), a transimpedance amplifier (continuous-time current) and transcapacitance circuits which can be based on a continuous-time or discrete-time approach (as discussed in Navid Yazdi, Haluk Kulah and Khalil Najafi, “Precision Readout Circuits for Capacitive Microaccelerometers”, Proceedings of IEEE Sensors, 2004).

An additional challenge for capacitive sensor interfaces is that for many applications, the circuitry for powering the capacitive sensor interface is typically battery operated. One such application is in the biomedical field, more particularly, implantable integrated circuits used in the biomedical field. Such applications typically provide low driving supply voltages and require low-power consumption. A number of such circuitry has been proposed. M. Tavakoli and R. Sarpeshkar, “An Offset-Canceling Low-Noise Lock-In Architecture for Capacitive Sensing”, IEEE Journal of Solid-State Circuits, vol. 38, no. 2, pp. 244-253, February 2003 describes a 1.5-μm BiCMOS chip used for capacitive sensing in a single-ended configuration. However, the power consumed in Tavakoli's work is about 20 mW and the supply voltage used is about 5V. Andrea Baschirotto, A. Gola, E. Chiesa, E. Lasalandra, F. Pasolini, M. Tronconi, and T. Ungaretti, “A 1-g Dual-Axis Linear Accelerometer in a Standard 0.5-μm CMOS Technology for High-Sensitivity Applications”, IEEE Journal of Solid-State Circuits, vol. 38, no. 7, pp. 1292-1297, July 2003 describes a differential amplifier in 0.5-μm CMOS technology coupled with a switched-capacitor filter used in an accelerometer. However, the power consumed in Baschirotto's work is about 45 mW and the supply voltage used is about 5V. J. Wu, G. K. Fedder, and L. R. Carley, “A Low-Noise Low-Offset Capacitive Sensing Amplifier for a 50-μg/√Hz Monolithic CMOS MEMS Accelerometer”, IEEE Journal of Solid-State Circuits, vol. 39, no. 5, pp. 722-730, May 2004 describes a CMOS capacitive sensing amplifier for a monolithic MEMS accelerometer using a differential configuration in 0.5-μm CMOS technology. However, the power consumed in Wu's work is about 30 mW and the supply voltage used is about 5V. B. V. Amini, S. Pourkamali, M. Zaman, and F. Ayazi, “A New Input Switching Scheme for a Capacitive Micro-G Accelerometer”, 2004 VLSI Symposium on Circuits, Digest of Technical Papers, pp. 310-313 describes an input switching capacitive microaccelerometer interface circuit in 0.25 μm CMOS technology in a differential configuration. However, the power consumed in Amini's work is about 6 mW and the supply voltage used is about 2.5V. H. Kulah, J. Chae, N. Yazdi, and K. Najafi, “Noise Analysis and Characterization of a Sigma-Delta Capacitive Microaccelerometer”, IEEE Journal of Solid-State Circuits, vol. 41, no. 2, pp. 352-361, February 2006 describes a sigma-delta capacitive microaccelerometer system in 0.5 μm CMOS technology and in a differential configuration. However, the power consumed in Külah's work is about 7.2 mW and the supply voltage used is about 5V.

Hence, there exists a need for a method for converting a sensor capacitance under parasitic capacitance conditions and a CV converter circuit for converting a sensor capacitance under parasitic capacitance conditions that seek to address at least one of the problems discussed above.

### SUMMARY

In accordance with one aspect of the present invention, there is provided a method for converting a sensor capacitance under parasitic capacitance conditions, the method comprising the step of using a two stage operational amplifier (op-amp) in non-unity-gain configuration, wherein the two stage op-amp is chosen to be unstable in unity-gain configuration for reducing power consumption.

The method may further comprise using a non-unity-gain reset circuit for performing offset cancellation operations.

A reset may be carried out by modifying a bias current intensity flowing in a first stage of the two stage op-amp.

The method may further comprise using a common-mode feedback (CMFB) circuit for providing fully-differential operations.

The CMFB circuit may comprise a non-unity closed-loop gain.

The non-unity closed-loop gain of the CMFB circuit may be chosen based on a resistive divider and a current gain divider coupled to an output of the op-amp.

Another resistive voltage divider may be used to provide a reference voltage to the CMFB circuit according to a chosen closed-loop gain.

In accordance with another aspect of the present invention, there is provided a capacitance-to-voltage (CV) converter circuit for converting a sensor capacitance under parasitic capacitance conditions, the converter circuit comprising a two stage op-amp in non-unity-gain configuration, wherein the two stage op-amp is chosen to be unstable in unity-gain configuration for reducing power consumption.

The converter circuit may further comprise a non-unity-gain reset circuit for performing offset cancellation operations.

The non-unity reset circuit may comprise at least two switches having different impedances such that activating the reset circuit generates a non-unity gain ratio across the converter circuit.

The converter circuit may further comprise a reset circuit for modifying a bias current intensity flowing in a first stage of the two-stage op-amp.

The reset circuit may comprise a switch implemented in a biasing current branch of the first stage such that activating the switch modifies the biasing current intensity flowing in the first stage of the two-stage op-amp.

The converter circuit may further comprise a CMFB circuit for providing fully-differential operations.

The CMFB circuit may comprise a non-unity closed-loop gain.

The CMFB circuit non-unity closed-loop gain may be chosen based on a resistive divider and a current gain divider coupled to an output of the op-amp.

Another resistive voltage divider may be used to provide a reference voltage to the CMFB circuit according to a chosen closed-loop gain.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 is a schematic block diagram of a Capacitance-To-Voltage (CV) converter circuit coupled to a microelectromechanical systems (MEMS) sensor in an example embodiment.

FIG. 2(a) is a schematic circuit diagram of an input stage of an operational amplifier (op-amp) of the CV converter circuit.

FIG. 2(b) is a schematic circuit diagram of an output stage of the op-amp.

FIG. 3 is a graph of gain (in dB) vs. frequency (in Hz) for illustrating CV converter stability for different closed-loop gains.

FIG. 4 is a schematic block diagram illustrating connections between the op-amp and a non-unity gain common-mode feedback (CMFB) circuit 110 of the CV converter circuit.

FIG. 5 is a schematic circuit diagram illustrating a non-unity-gain CMFB circuit architecture in the example embodiment.

FIG. 6(a) is a schematic diagram showing a functional effect of the CMFB circuit architecture in FIG. 5.

FIG. 6(b) is a graph showing an open loop gain and a feedback factor of a CMFB feedback loop in the example embodiment, for explaining the CMFB operation principle.

FIG. 7(a) is a schematic diagram illustrating a non-unity-gain reset feedback scheme using two switches in the example embodiment.

FIG. 7(b) is a schematic circuit diagram representing the switches of FIG. 7(a) with equivalent resistors for illustrating the operation principle of the two-switch reset scheme performing a non-unity gain reset.

FIG. 8 is a schematic circuit diagram illustrating a switch for modifying a bias current flowing in the first stage of the op-amp in the example embodiment.

FIG. 9 is a Bode graph of closed-loop gain (in dB) vs. frequency (in Hz) of another implementation of the example embodiment in a non-unity gain reset configuration.

FIG. 10 is a Bode graph showing open-loop gain (in dB) and phase (in degrees) as functions of frequency (in Hz) of another implementation of the example embodiment.

FIG. 11(a) is a Bode graph showing open-loop gain (in dB) and phase (in degrees) as functions of frequency (in Hz) of another implementation of the example embodiment.

FIG. 11(b) is a Bode graph showing open-loop gain (in dB) and phase (in degrees) as functions of frequency (in Hz) of a typical CV converter CMFB circuit.

FIG. 12 is a graph of output voltage (in V) vs. time (in seconds) showing waveforms observed at a positive terminal and a negative terminal of a differential CV converter output in another implementation of the example embodiment.

FIG. 13 is a zoom view of FIG. 12.

FIG. 14 is a graph of CV converter output voltage (in V) vs. time (in seconds) of another implementation of the example embodiment.

FIG. 15 is a zoom view of FIG. 14.

FIG. 16 is a graph of noise power spectral density (in V²/Hz) vs. frequency (in Hz) of another implementation of the example embodiment for different chopping frequencies.

FIG. 17 is a schematic flowchart for illustrating a method for converting a sensor capacitance under parasitic capacitance conditions in an example embodiment.

### DETAILED DESCRIPTION

The example embodiment described below can provide an operational amplifier (op-amp) that produces low-noise, consumes low-power as well as is able to operate in low-voltages (e.g. lower than 1.8V). That is, transistors in the op-amp are able to work in weak inversion. The example embodiment can provide an implantable integrated circuit that can deal with weak bio-electrical and bio-mechanical signals which are typically low-frequency signals. The example embodiment can provide good linearity, high-resolution and effective noise rejection. The example embodiment can provide fully-differential architectures to achieve a high common-mode rejection ratio (CMRR) and a power supply rejection (PSRR) ratio with high-linearity. In addition, the example embodiment can provide an improved signal-to-noise ratio (SNR) with an op-amp output being rail-to-rail. The example embodiment can make use of a class AB output stage and obtain higher power efficiency. The example embodiment can achieve high-gain while using a low-voltage power supply. The example embodiment utilises a two-stage op-amp. In the example embodiment, for achieving low-noise, a continuous-time signal processing and/or chopper techniques can be used.

In addition, the example embodiment can deal with high parasitic input capacitance (e.g. due to the interconnection between a capacitive sensor and ASIC) to achieve a high-resolution (e.g. 16 bit) and high-bandwidth (for chopper stabilisation) circuitry while consuming a low current (e.g. less than 100 μA) with a 1.5V supply voltage, by using a two-stage op-amp.

Furthermore, the example embodiment can address bandwidth requirements for reducing gain losses that can arise due to chopper operations. The example embodiment can also address power overhead/consumption that can arise when a second amplifier stage is used.

The example embodiment described herein can provide electronic circuits associated with CV converter circuits and fully-differential high-resolution low-voltage and low-power versions of these circuits for use in continuous-time capacitive sensor readout circuits for biomedical applications and/or other capacitive readout architectures. The example embodiment can also enhance the power efficiency of a CV converter coupled to an external capacitive sensor.

The example embodiment can provide a CV converter architecture that implements a low-noise continuous-time approach and a class-AB output stage that maintains a desirable low quiescent current. The architecture can produce a rail-to-rail output voltage swing and can be capable of operating at a low supply voltage.

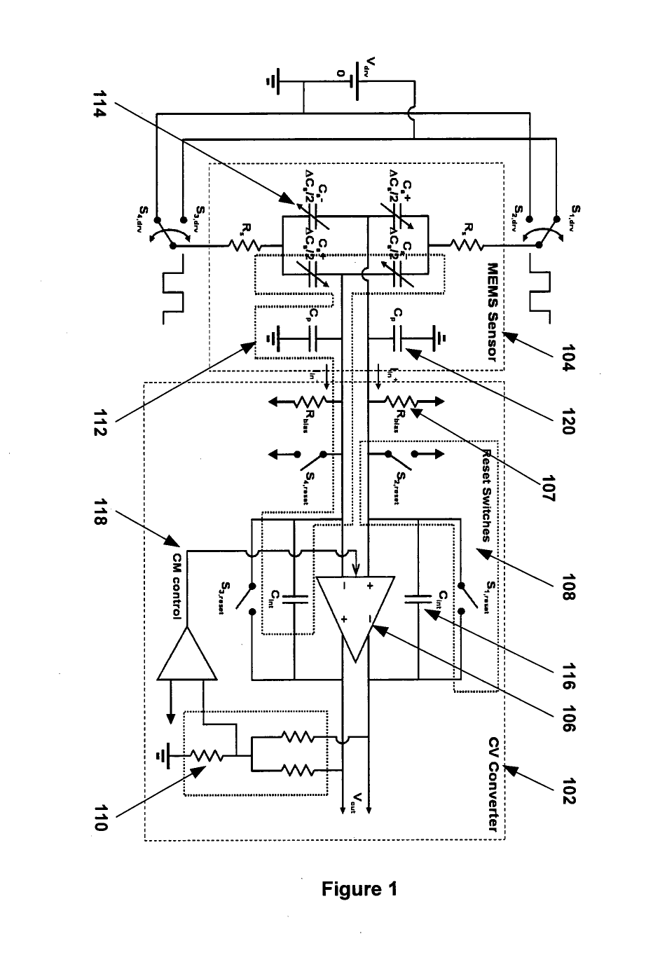

FIG. 1 is a schematic block diagram of a CV converter circuit 102 coupled to a MEMS sensor 104 in an example embodiment. The CV converter circuit 102 comprises an op-amp 106, a non-unity-gain reset feedback circuit 108 coupled to the op-amp 106 and a non-unity-gain CMFB circuit 110 coupled to the op-amp 106. In the example embodiment, the CV converter circuit 102 is configured to function in a non-unity gain mode. A non-unity-gain signal feedback loop 112 is formed between the op-amp 106 and the MEMS sensor 104.

In the example embodiment, the MEMS sensor 104 generates a capacitance change proportional to the acceleration sensed. By driving the MEMS sensor 104 with a voltage alternating between 0 and V_{drv}, a current Iᵢₙ having magnitude proportional to the capacitance change flows into and out of the CV converter circuit 102. This process can be viewed as up-converting the capacitance change signal residing in a baseband (e.g. 0 to 1 kHz) to the vicinity of a driving voltage alternation frequency. In this case, driving the MEMS sensor 104 in such a way with a square voltage wave has the same purpose as implementing an input chopper used for the so-called chopper stabilisation technique.

In the example embodiment, the up-converted current is integrated by an integrating capacitor Cᵢₙₜ e.g. 116 coupled between an output and an input of the op-amp 106 in the CV converter circuit 102. The integration thus generates an output voltage signal Vₒᵤₜ (=Vₒᵤₜ₊−Vₒᵤₜ₋) proportional to the capacitance change sensed in the MEMS sensor 104. An impedance R_{bias} e.g. 107 is connected in parallel to Cᵢₙₜ and is used to define a bias voltage at the high impedance input nodes of the CV converter circuit 102. The chopping frequency as well as the required resolution can be used to set the minimum bandwidth requirements for the op-amp 106 for the CV converter circuit 102.

In the example embodiment, the output noise spectrum density of the continuous-time CV converter circuit 102 can be approximated by the following equation (eq. 1) after down-conversion:

$${S}_{n , out} ( f ) \approx {( 1 + \frac{2 {C}_{s} + {C}_{p} + {C}_{in , amp}}{{C}_{int}} )}^{2} \cdot ( 1 + \frac{17}{2 {π}^{2}} \cdot \frac{{f}_{k}}{{f}_{chop}} ) \cdot {S}_{n , amp} ( f ) \qquad ( eq . 1 )$$

where C_{in,amp} is the input parasitic capacitance of the op-amp 106, S_{n,amp} is the input referred white noise spectral density of the op-amp 106, fₖ is the flicker noise corner frequency of the op-amp 106, f_{chop} is the chopping frequency for the chopper stabilised CV converter circuit 102. Cₛ refers to the capacitance of each sense capacitor e.g. 114 of the MEMS sensor 104 and Cᵢₙₜ refers to the capacitance of each integration capacitor e.g. 116 of the CV converter circuit 102. Cₚ is the parasitic capacitance e.g. 120 at the sense node due to e.g. the MEMS intrinsic parasitic capacitance and interconnection between the MEMS sensor 104 and the CV converter 102.

The input referred noise spectrum density of a fully differential op-amp can be approximated by:

$${S}_{amp - in} ( f ) \approx \frac{16}{3} \cdot \frac{{k}_{B} T}{{g}_{m , eq}} \qquad ( eq . 2 )$$

where g_{m,eq} is the equivalent transconductance of the input differential pair of transistors in the op-amp.

It has been recognised by the inventors, that to achieve a large SNR, the input op-amp transconductance g_{m,eq} is desired to be as high as possible, thereby incurring large biasing currents. In addition, the op-amp output is desired to be rail-to-rail. Further, the op-amp open-loop gain is desired to be high so that high-linearity and low-gain error can be obtained. Thus, in the example embodiment, a two-stage folded-cascode op-amp is used with a rail-to-rail output stage and a wide-swing input common-mode range (i.e. to be less sensitive to input common-mode voltage drift due to current leakage at a high impedance input node).

In relation to stability problems of conventional two stage op-amps, generally at the design phase, attention is paid to possible problems of frequency response. To design a stable two-stage op-amp in a unity-gain configuration, the transconductance g_{m1,eq} and g_{m2,eq} (i.e. equivalent transconductance of the first and second stages respectively), the load C_{L} and the compensation capacitance C_{c} (assuming a Miller compensation approach) should satisfy the following condition [as discussed in Willy M. C. Sansen, “Analog Design Essentials”, Springer 2007, p 149-180]:

$$\frac{{g}_{m 2 , eq}}{{g}_{m 1 , eq}} = 4 \cdot \frac{{C}_{L}}{{C}_{C}} ⇒ {g}_{m 2 , eq} = 4 \cdot \frac{{C}_{L}}{{C}_{C}} \cdot {g}_{m 1 , eq} \qquad ( eq . 3 )$$

An op-amp that satisfies eq. 3 typically has a resulting large output quiescent current which gives rise to poor power efficiency.

It will be appreciated by a person skilled in the art that a two-stage op-amp is typically designed to be stable in a unity-gain configuration so as to ensure the op-amp stability regardless of the feedback, since the unity-gain configuration is a worst case scenario. Besides, designing an op-amp that is not stable in the unity-gain configuration assumes that a non unity-gain feedback condition is always held during any period of the system operation. However, typically during reset phases, the op-amp is configured in a different way, involving a unity-gain feedback arrangement. Further, in the case of a fully-differential op-amp, it will be appreciated that one has to take into consideration the stability of the CMFB circuit loop (ie. the CMFB feedback loop is not the same as the main op-amp feedback loop), the CMFB circuit loop being in a unity-gain configuration. As a consequence, using a non-stable op-amp in the unity-gain configuration typically results in a poorer stability behaviour for the CMFB circuit as the CMFB circuit loop includes the op-amp itself. Thus, in view of the above considerations, a two-stage op-amp is typically designed to be stable in the unity-gain configuration.

An alternative approach is described in U.S. Pat. No. 5,990,748 for providing an adaptive self-compensated two-stage op-amp that is stable in a unity gain configuration that requires higher power consumption to reduce the generated noise. This approach provides a way to self-compensate a single-ended op-amp accordingly with the feedback factor, or the closed-loop gain, so as to maximize the bandwidth for a given power consumption. U.S. Pat. No. 5,990,748 does not propose any solution in the case of a fully-differential architecture, and more particularly, any solution on how to deal with the CMFB loop stability.

In low-power CMOS design, transistors work in moderate- and/or weak-inversion region. Thus, for a given current, the transconductance is substantially independent of the overdrive voltage [as discussed in Gray, Hurst, Lewis, Meyer, “Analysis and Design of Analog Integrated Circuits”, John Wiley & Sons, Fourth Edition 2004, p 68-69]. In addition, the op-amp gain-bandwidth (GBW) product is desired to be high compared to the chopping frequency so as to minimize gain error and/or gain variation. The op-amp gain bandwidth product is given by:

$$GBW = \frac{{C}_{C}}{{g}_{m 1 , eq}} \qquad ( eq . 4 )$$

The op-amp closed-loop bandwidth is related to the integration capacitance Cᵢₙₜ e.g. 116, the input parasitic capacitance Cₚ e.g. 120 and the sense capacitance Cₛ e.g. 114.

It has been recognised by the inventors that, in an exemplary accelerometer with external MEMS sensors (assuming that the MEMS and the ASIC are not designed on the same silicon substrate), parasitic capacitance can be equal to a few pico-Farad up to hundreds of pico-Farad. Therefore, the closed-loop gain of a CV converter used with the exemplary accelerometer is always greater than one. This follows from the closed-loop gain equation, eq. 5, below:

$${G}_{CL} = \frac{2 {C}_{s} + {C}_{p}}{{C}_{int}} \qquad ( eq . 5 )$$

In the example embodiment, the following values are set, Cₛ=0.9 pF, Cₚ^{max}=5 pF and Cᵢₙₜ=200 fF. The value of Cᵢₙₜ is chosen so as to maximize the output voltage with regard to e.g. a maximum input acceleration (e.g. 6.5 g) of an accelerometer. Thus, the closed-loop gain in the example embodiment can be as low as about 10 and as high as about 35 depending on the value of Cₚ.

The inventors have further recognised that for the two-stage op-amp in the example embodiment, there is no need to ensure stability in the unity gain configuration for the CV converter circuit 102 to be stable when it is working to sense capacitance change. The example embodiment uses a two-stage op-amp in non-unity gain configuration, wherein the two-stage op-amp is intentionally chosen to be unstable in unity-gain configuration for reducing power consumption.

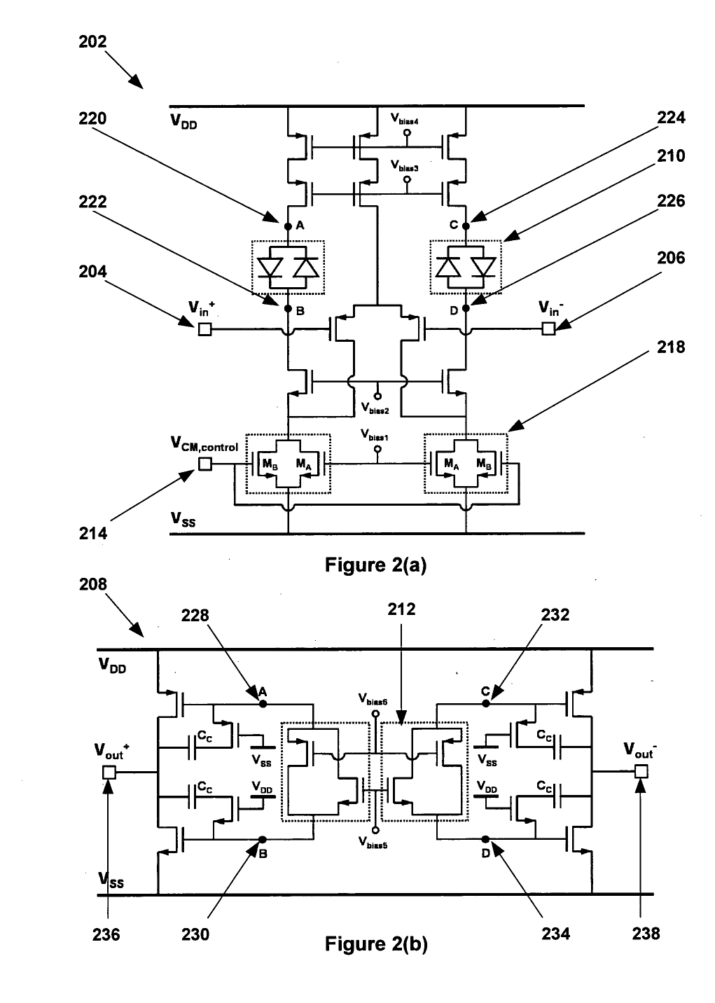

FIG. 2(a) is a schematic circuit diagram of an input stage 202 of the op-amp 106 (FIG. 1) in the example embodiment. In the example embodiment, the input stage 202 is a folded-cascode input stage. The outputs from the MEMS sensor 104 (FIG. 1) are connected to respective inputs 204, 206 of the input stage 202. The output of the amplifier following the non-unity gain CMFB circuit 110 (see 118 of FIG. 1) is connected to node 214 of the input stage 202.

FIG. 2(b) is a schematic circuit diagram of an output stage 208 of the op-amp 106 (FIG. 1) in the example embodiment. In the example embodiment, the output stage 208 is a class-AB output stage. The input stage 202 is connected with the output stage 208 at four nodes; ie. nodes 220, 222, 224 and 226 in the input stage 202 correspond to nodes 228, 230, 232 and 234, respectively. A back-to-back connected diode pair 210 in the input stage 202 appears in FIG. 2(b) at numeral 212 to show its actual transistor-level implementation. Output nodes 236 and 238 of the output stage 208 are the outputs of the op-amp 106 (FIG. 1) and are connected to the non-unity gain CMFB circuit 110 (FIG. 1).

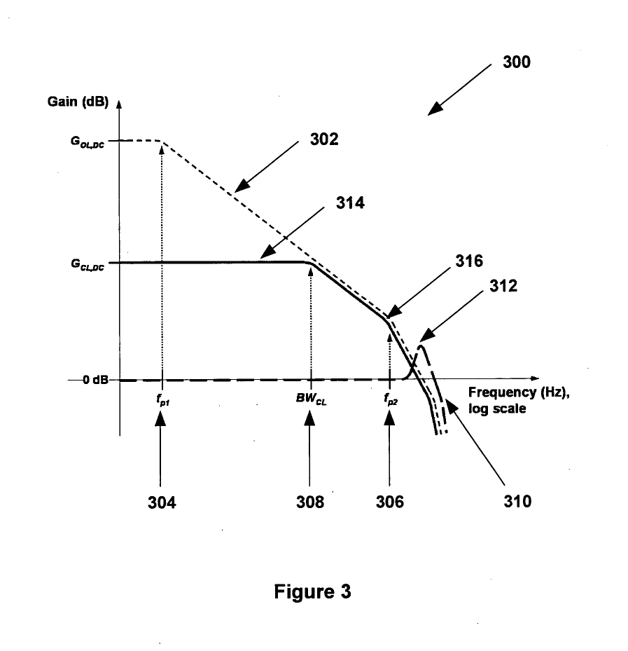

FIG. 3 is a graph 300 of gain (in dB) vs. frequency (in Hz) for illustrating CV converter stability for different closed-loop gains. The graph 300 shows the frequency response for an exemplary amplifier having a predetermined compensation. An open-loop gain plot 302 shows the two poles 304, 306 corresponding to the frequency responses of the input stage and output stage of the amplifier respectively. Numeral 308 indicates a design requirement of the closed-loop bandwidth. A unity closed-loop gain plot 310 of the amplifier shows that the amplifier is unstable since the response at numeral 312 shows significant peaking after the second pole 306 of the open-loop gain characteristics. On the other hand, for a non-unity gain configuration, a non-unity gain closed-loop gain plot 314 shows that the amplifier is stable while still meeting the bandwidth requirement since the response at numeral 316 is before the second pole 306 of the open-loop gain characteristics.

By having a non-unity closed-loop gain, an additional advantage is that the power consumption of the second stage 208 can be reduced by almost one order of magnitude. It is repeated here that in contrast to U.S. Pat. No. 5,990,748, the CV converter circuit 102 (FIG. 1) of the example embodiment is not designed to be frequency self-compensated according to the closed-loop gain.

If the closed-loop gain G_{CL} is greater than 1 (ie. non-unity), then eq. 3 becomes:

$${g}_{m 2 , eq} = 4 \cdot \frac{{C}_{L}}{{C}_{C}} \cdot \frac{{g}_{m 1 , eq}}{{G}_{CL}} \qquad ( eq . 6 )$$

In weak inversion, eq. 6 can be interpreted as a reduction of the output quiescent current by a factor G_{CL}, which improves substantially the power efficiency of the CV-converter circuit 102 (FIG. 1). This is true since in weak inversion regions, the transistor transconductance gₘ is proportional to the current. In other words, current consumption of the output stage can be reduced by a factor of G_{CL}.

It will be appreciated that a fully-differential op-amp uses a CMFB circuit to operate properly. Typically, a CMFB circuit senses the output common-mode voltage of a fully-differential amplifier and provides a common-mode control signal which controls some current biasing structures within the differential amplifier to maintain a proper common-mode output voltage, and hence a correct fully-differential operation. Thus, typically, the CMFB loop-gain is equal to unity. In contrast, in the example embodiment, the common-mode sense circuit comprises a resistive network which is designed in such a way so as to provide a non-unity CMFB loop-gain.

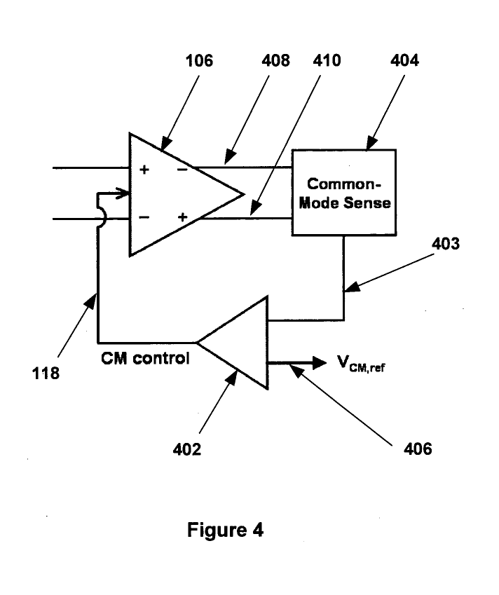

FIG. 4 is a schematic block diagram illustrating connections between the op-amp 106 and the non-unity gain CMFB circuit 110 of FIG. 1. As shown in FIG. 4, the op-amp 106 receives the common-mode control signal 118 as the output of a CMFB amplifier 402. The amplifier 402 has as its inputs a common-mode sense signal 403 from a common-mode sense circuit 404 and a common-mode reference voltage 406 (V_{CM,ref}). The common-mode sense circuit 404 in turn has the output signals 408, 410 from the op-amp 106 as its inputs. The common-mode sense circuit 404 uses the signals 408, 410 to sense the output common-mode voltage of the op-amp 106 and to feed the CMFB amplifier 402 with this sense signal 403.

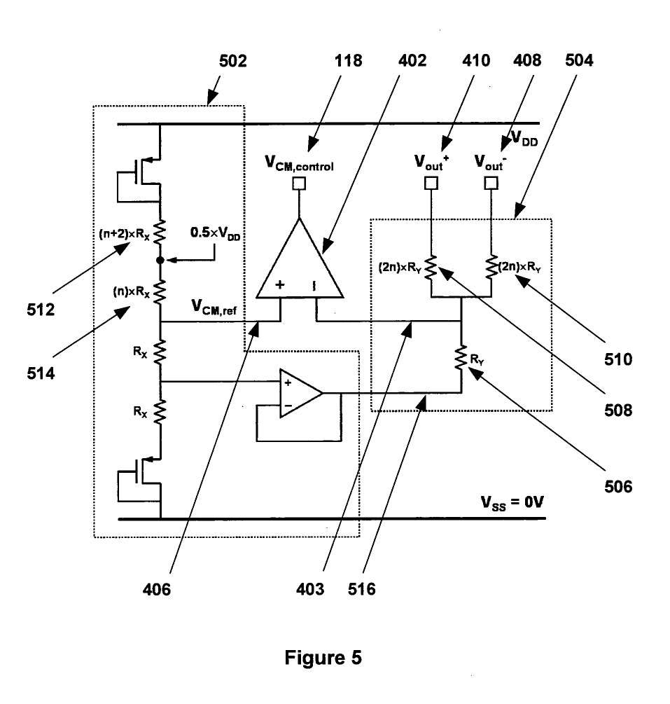

FIG. 5 is a schematic circuit diagram illustrating the non-unity-gain CMFB circuit architecture in the example embodiment. A first resistive network 504 is provided for functioning as the common-mode sense circuit 404 (FIG. 4) to provide the common mode sense signal 403. A resistor 506 is added in the first resistive network 504 to configure a non-unity-gain CMFB loop. A second resistive network 502 is provided to generate the common-mode reference voltage signal 406 (V_{CM,ref}) of FIG. 4 and another bias voltage 516 to improve the power efficiency of the CMFB circuit 110 (FIG. 1) further.

In the example embodiment, as the common-mode control signal 118 is connected to node 214 of the op-amp first stage 202, the CMFB stability is improved by increasing the ratio (W/L)_{MA}/(W/L)_{MB} (see numeral 218 of FIG. 2(a)) within a certain range (e.g. ratio of not larger than 4 to ensure normal operation of the CMFB under the worst-case process variation or large common-mode disturbance from the environment). (W/L)_{MA} and (W/L)_{MB} are the ratios between channel width W and length L of MOSFETs M_{A} and M_{B} in FIG. 2(a), respectively. Typically, due to the limited range of the ratio (W/L)_{MA}/(W/L)_{MB} in this technique, a large current or power still needs to be consumed to achieve a stable CMFB loop.

It is noted that large current biasing for the CMFB circuit is to be avoided, to reduce the overall power consumption. Thus, in contrast, in the example embodiment, to improve further the CMFB stability while consuming low-power, the CMFB closed-loop gain is also increased to be non-unity by modifying the feedback resistive network 504. In this configuration, the closed-loop gain is directly proportional to (n+1) (refer to resistors 506, 508, 510, 512, 514). In the example embodiment, the purpose of the resistive voltage divider network 502 is to provide desired reference voltages to the CMFB according to a chosen closed-loop gain. The closed loop gain is chosen so as to achieve a required stability. The closed loop gain not only depends on the differential amplifier 106 (FIG. 1) but also on the CMFB amplifier 402 (FIG. 4) used.

In addition, by providing the additional bias voltage 516 which is non-zero, the power efficiency of the resistive network 504 can be improved. The inventors have recognised that since large-valued resistors are difficult to be implemented in IC technology due to area constraints, reducing the voltage applied across the resistive divider circuit network 502 is an effective way to reduce current consumption. Therefore, using the CMFB biasing circuit architecture with network 502, both passive power consumption and silicon area consumption can advantageously be reduced.

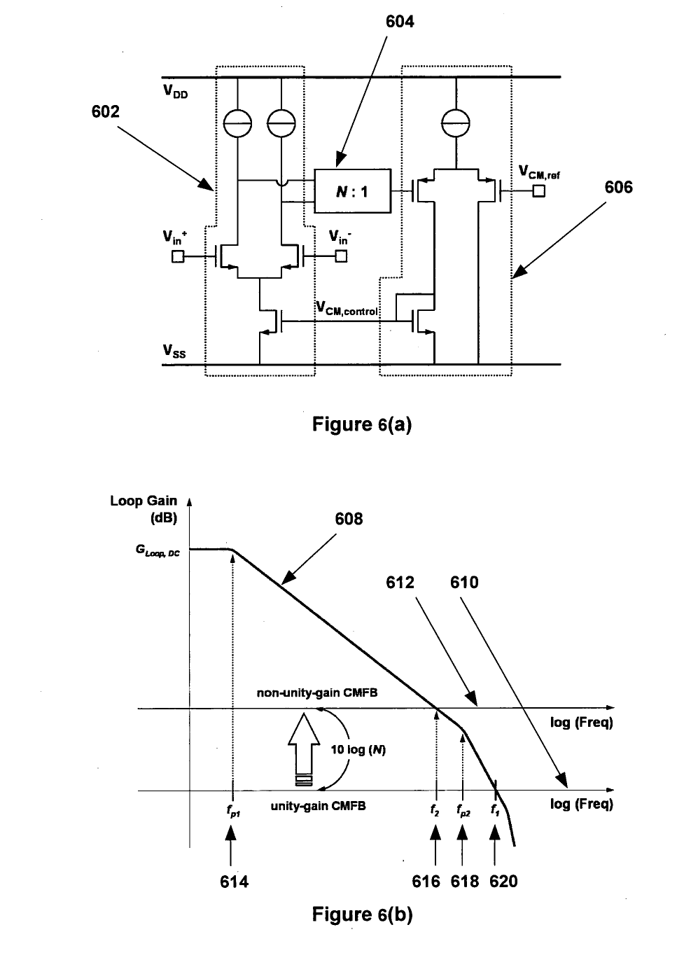

FIG. 6(a) is a schematic diagram showing the effect of the CMFB circuit architecture in FIG. 5. In this example, the differential output voltages of an op-amp 602 are connected to a common-mode sense circuit 604 to generate a common-mode sense signal which is a scaled replica of the common-mode output voltage of the op-amp 602. The scaling ratio used in the common-mode sense circuit 604 is N:1 where N can be set based on a CMFB architecture of the example embodiment (compare 504 and 502 of FIG. 5), and it can be shown that N equals to (n+1) in FIG. 5.

FIG. 6(b) is a graph showing the effect of the non-unity-gain CMFB on the loop gain of the CMFB feedback loop and its stability. A curve 608 represents the CMFB loop gain and the frequencies fₚ₁ 614 and fₚ₂ 618 are the first and second poles respectively. The effect of using the CMFB circuit architecture (compare FIG. 5) is to “raise” the x-axis of the graph by a factor of 10 log (n+1), or 10 log (n+1) in dB scale. The x-axes 610 and 612 correspond to the case when the CMFB loop is configured in unity gain and non-unity gain respectively. In a unity-gain CMFB configuration (refer to x-axis 610), the loop gain falls to 0 dB at frequency of f₁ 620, which comes after fₚ₂ 618 and causes instability. On the other hand, in a non-unity gain CMFB of the example embodiment (refer to x-axis 612), the loop gain curve 608 crosses the x-axis at f₂ 616 coming before fₚ₂ 618 and the CMFB operation is stable.

Having described how the CMFB circuit stability can be improved, the following paragraphs describe the non-unity gain reset feedback circuit 108 (FIG. 1) of the CV converter circuit 102 (FIG. 1) in the non-unity gain configuration.

In the example embodiment, having provided a CV-converter op-amp 106 (FIG. 1) that has a larger closed-loop gain than unity (i.e. having a non-unity gain) when it performs normal readout operation, during the reset phase, which is carried out to reset all capacitance involved in e.g. an entire capacitive sensor system comprising the MEMS sensor 104 (FIG. 1) and the CV converter circuit 102 (FIG. 1), the op-amp 106 is connected in a follower configuration to perform offset cancellation operation at the same time as the reset operation. Thus, if a typical reset circuit that simply shorts the two plates of the Cᵢₙₜ capacitor 116 is used, the CV converter circuit 102 (FIG. 1) enters the unity gain configuration and can have an oscillatory response.

Therefore, to avoid entering the unity gain configuration during the reset phase, the non-unity-gain reset feedback circuit 108 (FIG. 1) is provided to perform a non-unity-gain reset. The circuit in the example embodiment can be provided using the two-switch circuit as illustrated in FIG. 1 (see switches S_{1,reset} and S_{2,reset}).

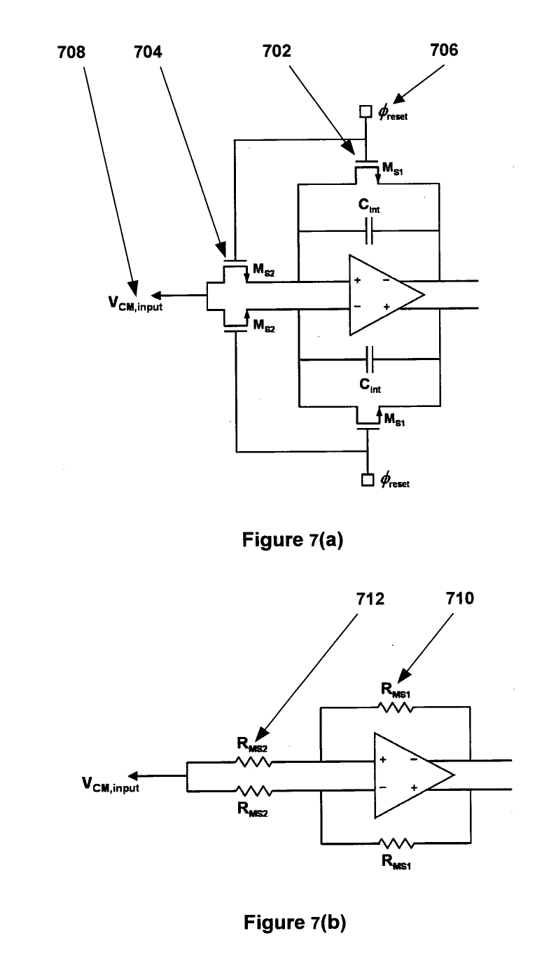

FIG. 7(a) is a schematic diagram illustrating the non-unity-gain reset feedback scheme using two switches for each reset feedback path. A first switch M_{S1} 702 and a second switch M_{S2} 704 are implemented with MOSFETs in this example embodiment. During the reset phase, a signal φᵣₑₛₑₜ 706 is asserted such that M_{S1} 702 and M_{S2} 704 are turned on and operate in a linear region. A bias voltage V_{CM,input} 708 is connected to one end of M_{S2} 704 to define the input common-mode voltage, which is usually set such that V_{CM,input}=V_{CM,output} (output common-mode voltage)=0.5×V_{DD}, where V_{DD} is the voltage supply. The MOSFET switches M_{S1} 702 and M_{S2} 704 are sized such that (WV/L)_{MS1}:(W/L)_{MS2}=K:1 and hence, a loop gain of K (>1) can be obtained (i.e. non-unity gain). (W/L)_{MS1} and (W/L)_{MS2} are the ratios between channel width W and length L of MOSFETs M_{S1} and M_{S2}, respectively. In the example embodiment, M_{S1} 702 corresponds to S_{1,reset} and M_{S2} 704 to S_{2,reset} in FIG. 1.

FIG. 7(b) is a schematic circuit diagram representing the reset switches in FIG. 7(a) with their equivalent resistances to better show the non-unity gain reset configuration. Resistors R_{MS1} 710 and R_{MS2} 712 represent the equivalent resistance of the switches M_{S1} 702 and M_{S2} 704 of FIG. 7(a) respectively. The resistor values are designed such that a ratio R_{MS1}>R_{MS2} can be obtained to make closed-loop gain of the reset switch network or the reset circuit 108 (FIG. 1) larger than unity.

Alternatively, instead of manipulating the closed-loop gain of the reset switch network or the reset circuit 108 (FIG. 1) (as illustrated in FIGS. 7(a) and (b)), the bias current flowing in the first stage 202 (FIG. 2(a)) can be controlled, depending on the CV converter operation modes (e.g. reset and normal readout modes).

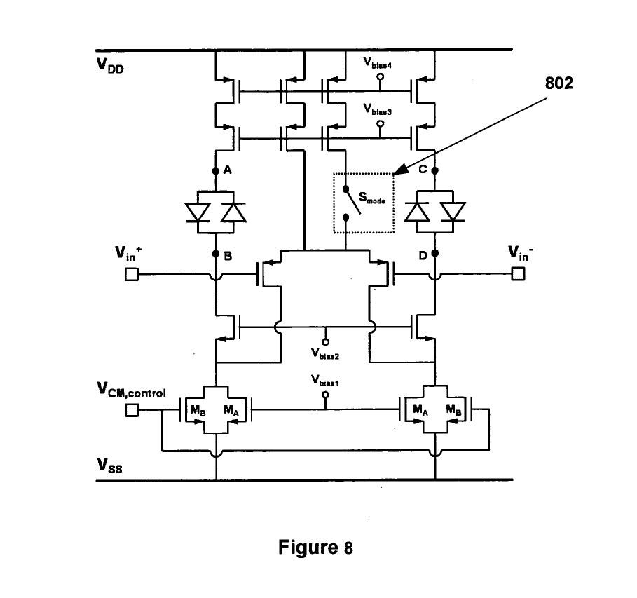

FIG. 8 is a schematic circuit diagram illustrating a switch 802 for modifying a bias current flowing in the first stage 202 of FIG. 2(a). In this alternative, the switch 802 is used to switch off a portion of current flowing in the first stage 202 during the reset phase. In this way, the condition set by eq. 3 can be satisfied with less current consumption in the second stage 208 of FIG. 2(b). However, this method deals directly with the op-amp circuitry and not with the feedback configuration. Although this alternative is simpler to implement, one drawback of this alternative compared to the reset switch network of FIG. 7(a) is that the switch 802 allows only a partial offset cancellation as the bias current of the input stage is different from its actual value set during a normal readout operation.

Thus, the example embodiment described above can achieve a high-resolution (e.g. 16 bit) and a wide-bandwidth (for chopping purposes) circuitry while consuming a low-current (e.g. less than 100 μA) with a low 1.5V supply voltage, by using a two-stage op-amp. The example embodiment described above can meet bandwidth requirements to avoid gain losses that can arise due to chopping. The example embodiment described above can also reduce power overhead/consumption that arises from using a second amplifier stage and a fully-differential architecture.

In one implementation of the above example embodiment, it is found that power consumption of a second amplifier stage is reduced from about 150 μW operating in a unity gain configuration to about 30 μW operating in a non-unity gain configuration. That is,

Total power consumption Pₜₒₜₐₗ=(P_{1st-stage}+P_{2nd-stage}) was reduced from (48 μW+150 μW) to (48 μW+30 μW), where P_{1st-stage} and P_{2nd-stage} are the power consumed in the 1^{st} folded-cascode stage and the 2^{nd} class-AB stage, respectively.

Table 1 below summarizes the CV converter circuit performances in another implementation of the above example embodiment.

TABLE 1

| Parameter | Performance | Condition |
|---|---|---|
| Supply Voltage | 1.35 to 1.65 V | |
| Current Consumption | 82.4 μA | |
| Output Swing Range | ±1.2 V | Differential peak-to-peak |
| DC Loop Gain | >76.5 dB | |
| GBW | >21 MHz | |
| Total Harmonic | <0.03% | Tested with 7-Hz, ±1.2-V |
| Distortion | | sinusoidal input at 1.5-V supply |
| Phase Margin | >70° | |
| Loading | 0.5 pF/100 kΩ | |
| Output-Referred Noise | 12 uVrms | Integrated over 1μ to 400 Hz |
| Area | 0.072 mm² | |

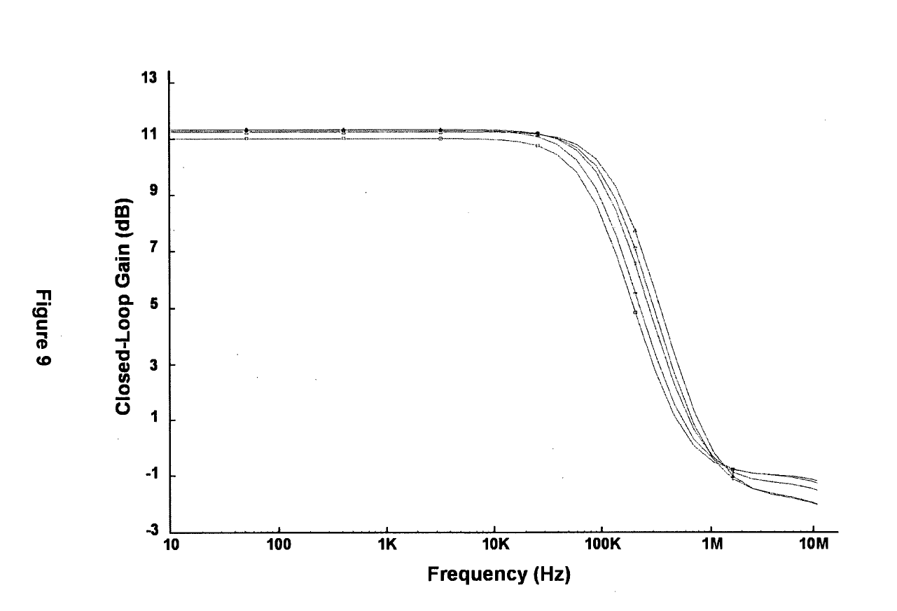

FIG. 9 is a Bode graph of closed-loop gain (in dB) vs. frequency (in Hz) of another implementation of the example embodiment used in a reset mode. In a reset-mode configuration, with a closed-loop gain of 4 through the use of a switch size ratio of 4, the CV converter circuit is stable as no overshoot is detectable in the closed-loop gain AC analysis.

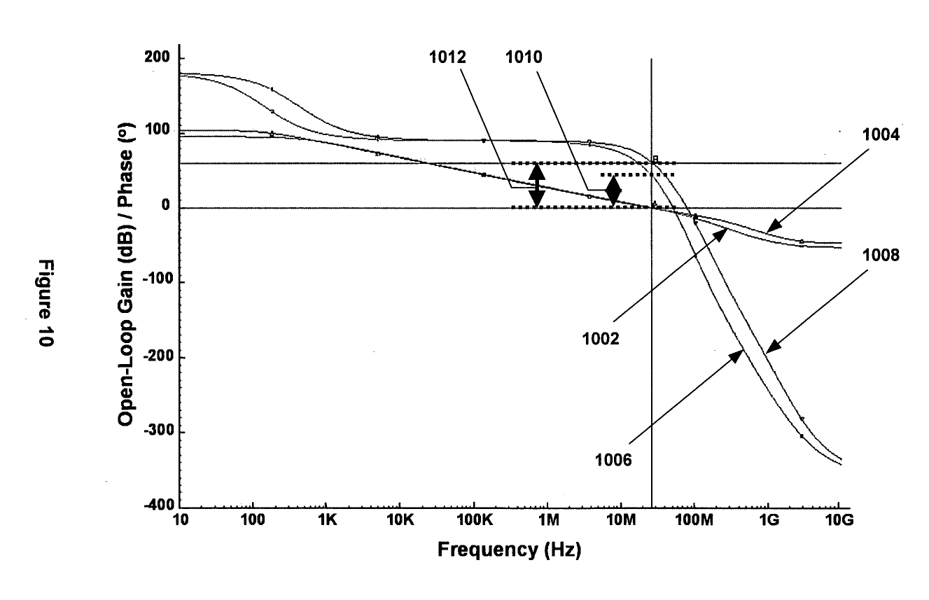

FIG. 10 is a Bode graph showing open-loop gain (in dB) and phase (in degrees) as functions of frequency (in Hz) of another implementation of the example embodiment for two different output stage bias currents. Plot 1002 shows an open loop gain curve for an output stage bias current of about 10 μA and plot 1004 shows an open loop gain curve for an output stage bias current of about 50 μA. Plot 1006 shows a phase curve for the 10 μA scenario and plot 1008 shows a phase curve for the 50 μA scenario. The output load in this implementation is set as 0.5 pF/100 kΩ. For the 10 μA output stage quiescent current scenario, at unity gain (ie. at 0 dB), the phase margin (for plot 1006) is only about 45° (refer to numeral 1010). This shows that the example implementation does not ensure stability in all process and temperature corners if it is used in unity-gain configuration.

The inventors have recognised that if the non-unity-gain reset feedback circuit 108 (FIG. 1) and the non-unity-gain CMFB circuit architecture (see FIG. 5) are not applied, the stability of the system has to be improved in the unity-gain configuration. Typically, this would comprise compensating the two-stage op-amp resulting in a poorer bandwidth or increasing the output stage bias current, which incurs a higher power consumption. For illustration only, by increasing the output stage bias current to about 50 μA, it can be seen that the phase margin (for plot 1008) reaches about 60° (refer to numeral 1012). It is pointed out that compensation or increasing bias current is not carried out in the example embodiments because the two-stage op-amp is intentionally chosen to be unstable in unity-gain configuration for reducing power consumption. In the present implementation, the CV converter cannot be configured in unity gain configuration. The reset circuit and the CMFB circuit of the example implementation are configured so as to ensure that the CV converter does not operate in a unity gain mode.

Table 2 summarizes the simulation results of phase margin of another implementation of the example embodiment obtained for different closed-loop gain values for the op-amp and different output stage biasing currents. Particularly, it shows that to obtain a phase margin of about 70°, for a closed-loop gain of 10, the biasing current of the output stage is about 7 μA compared to about 3 μA only for a closed-loop gain of 20. This can advantageously reduce the power consumption of the class-AB output stage. The column showing the phase margin for the closed loop gain of 0 dB is used to show the improvement in terms of phase margin of the example implementation in a non-unity gain configuration over a control circuit in a unity gain configuration consuming the same current. For example, for a closed-loop gain of 0 dB, a phase margin of 67 can only be obtained at the cost of 50 μA current consumption at the output stage for the control circuit while less than 7 μA is consumed for the example implementation when the closed-loop gain is 10 dB.

TABLE 2

| | Phase Margin for | | |
|---|---|---|---|
| Output Stage | Different Closed-Loop Gains | | |
| Bias Current | Closed-Loop Gain = 0 | 10 | 20 |
| 3 μA | <0 | 54 | 73 |
| 7 μA | 19 | 71 | 82 |
| 9 μA | 35 | 75 | 84 |
| 12 μA | 41 | 78 | 85 |
| 27 μA | 59 | 83 | 87 |
| 49 μA | 67 | 85 | 88 |

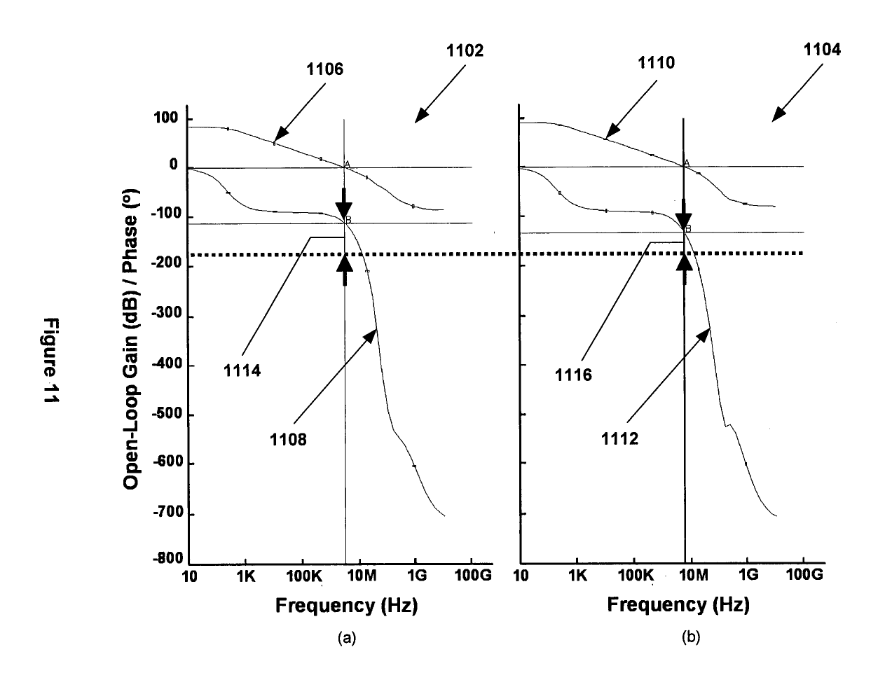

FIG. 11(a) is a Bode graph 1102 showing open-loop gain (in dB) and phase (in degrees) as functions of frequency (in Hz) of another implementation of the example embodiment. FIG. 11(b) is a Bode graph 1104 showing open-loop gain (in dB) and phase (in degree) as functions of frequency (in Hz) of a typical CV converter CMFB circuit. Plot 1106 shows an open loop gain curve and plot 1108 shows a phase curve for the CMFB circuit for the example implementation. Plot 1110 shows an open loop gain curve and plot 1112 shows a phase curve for the typical CV converter CMFB circuit. It can be observed that the example implementation improves the stability of the loop for the CMFB circuit. Under the same loading condition, the CMFB phase margin for the typical CV converter (refer to numeral 1116) is approximately 47° as compared to about 67° (refer to numeral 1114) for the CMFB phase margin for the example implementation. Thus, it can be observed that the example implementation results in a 20° phase margin improvement for the CMFB circuit. It is noted that for the typical CV converter to obtain a 60° phase margin for the CMFB circuit, the quiescent current of the output stage should be increased that in turn incurs higher power consumption.

The FIGS. 5(a) and (b) comparison show that since the CMFB circuit is stable at the unity gain configuration (i.e. worst case scenario), the CMFB circuit can be stable at non-unity configurations.

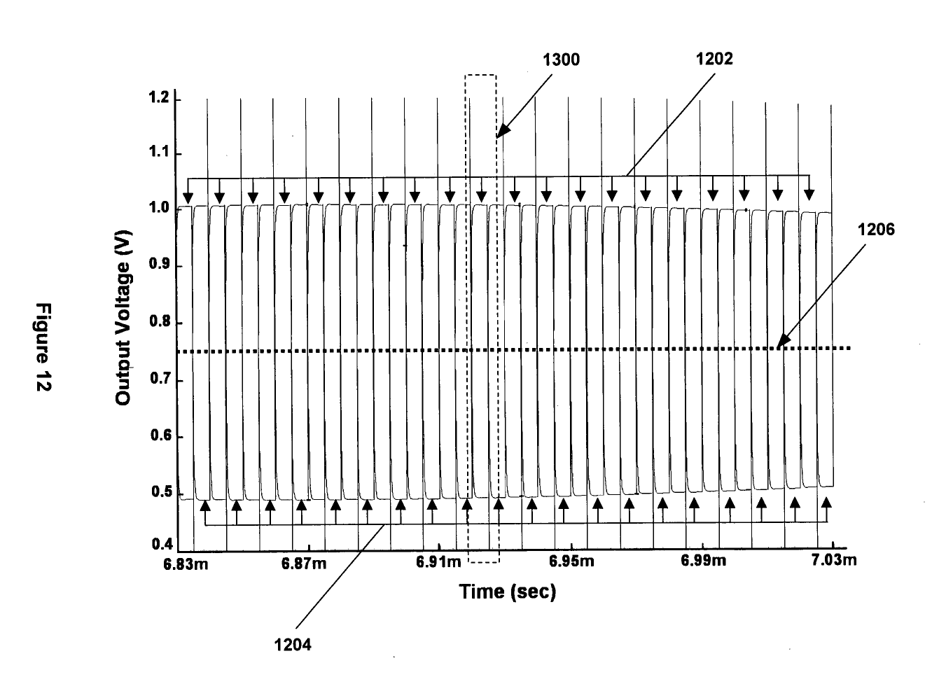

FIG. 12 is a graph of output voltage (in V) vs time (in seconds) showing waveforms observed at a positive terminal (refer to numeral 1202) and a negative terminal (refer to numeral 1204) of a CV converter output (compare FIG. 1) in another implementation of the example embodiment. The graph shows the output waveforms for a chopped sinusoidal input signal. Numeral 1206 represents the ideal common-mode output voltage. Transient analysis can confirm that the CV converter circuit of this example implementation is stable as no ringing waveform can be observed.

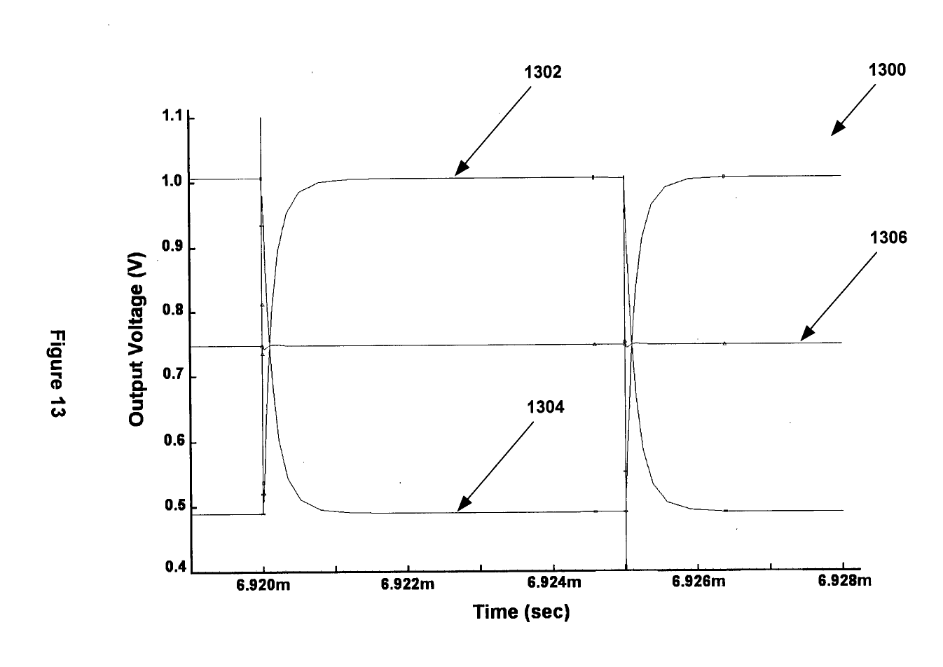

FIG. 13 is a zoom view 1300 of FIG. 12. The common-mode output voltage 1306 can be observed from this graph. Again, this graph confirms that the CV converter circuit is stable as no ringing waveform can be observed in the differential signals 1302 and 1304 and also in the common-mode output voltage 1306.

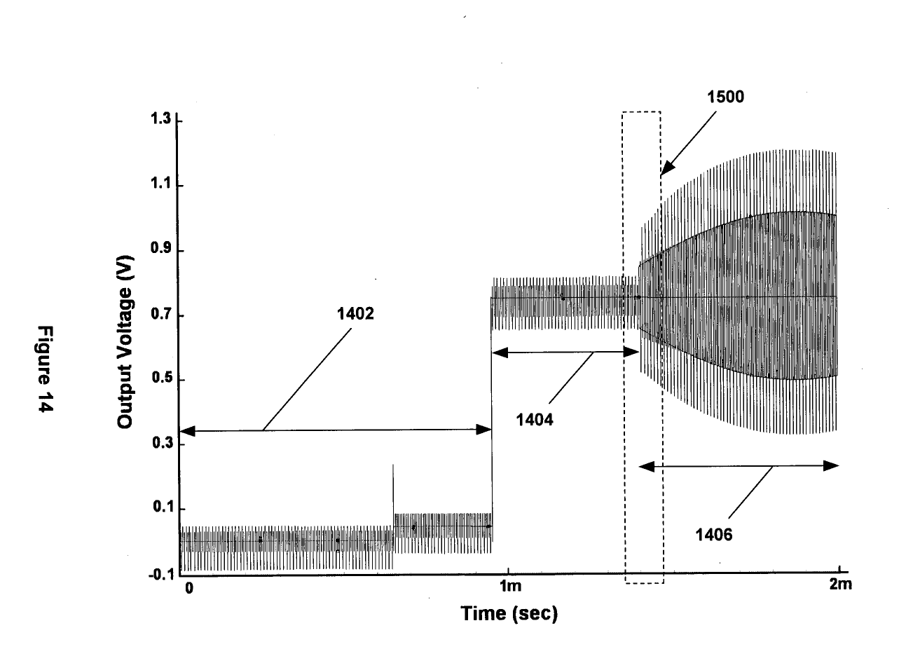

FIG. 14 is an output voltage (in V) vs time (in seconds) graph of another implementation of the example embodiment. This graph shows the CV converter circuit output transient waveform in order to analyze the behaviour of the circuit during start-up (compare 1402), its reset mode (compare 1404) and its normal operation (compare 1406). Transient analysis can confirm that the CV converter circuit of this example implementation is stable as no ringing waveform can be observed during operation across these different modes.

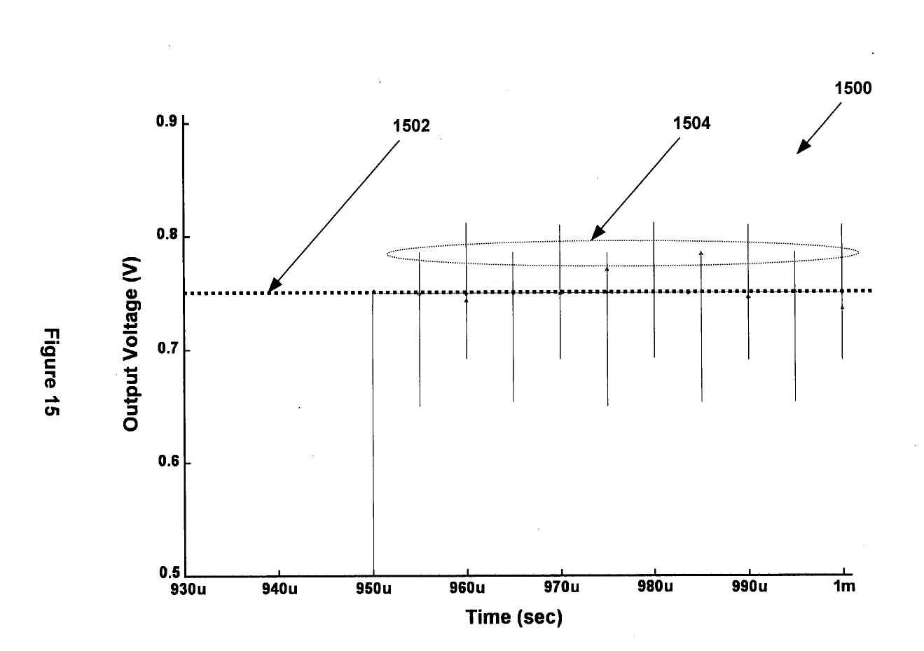

FIG. 15 is a zoom view 1500 of FIG. 14. The graph confirms that the output voltage is set to half the power supply voltage (compare 1502). The chopping clock frequency can be observed in the reset phase waveform (compare 1504). Again, the graph confirms that the CV converter circuit is stable as no ringing waveform can be observed.

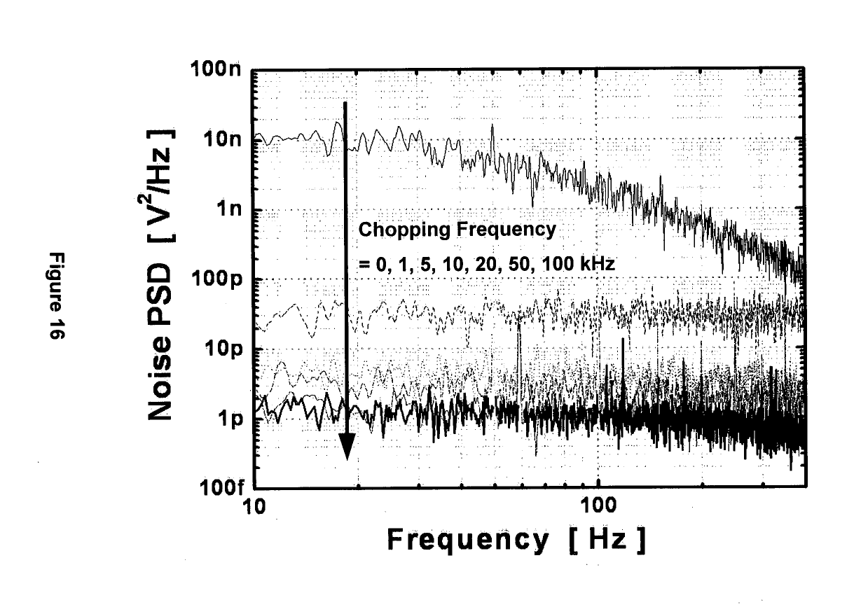

FIG. 16 is a graph of noise power spectrum density (in V²/Hz) vs frequency (in Hz) of another implementation of the example embodiment. The noise spectrum density is obtained both with and without chopper stabilization with a closed loop gain of 5. Without chopping (corresponding to the 0 Hz case in the graph), the flicker noise is the dominant noise contributor. The chopping frequency is set to 1 k, 5 k, 10 k, 20 k and 50 kHz successively to remove the flicker noise to a further extent.

Table 3 below tabulates the performance of another implementation of the example embodiment. As can be observed, the implementation consumes very low power and supply voltage while providing excellent performance ie. generating low noise, low distortion, and having a large dynamic range. Dynamic range or DR is defined to be Power(Max signal output)/Power(noise floor).

TABLE 3

| | |
|---|---|
| Chopping Frequency | 100 kHz |
| Total Differential Output Noise for | 12 μVᵣₘₛ |
| 400 Hz Bandwidth | |
| Power Consumption | 124 μW |
| Total Harmonic Distortion at Full | <0.03% |
| Signal Swing (1.2 Vₚₚ at 1.5 V | |
| supply) | |
| Dynamic Range | 100 dB |

Furthermore, a figure of merit (FOM) is defined as follows in S. Rabii, B. A. Wooley, “A 1.8-V Digital-Audio Sigma-Delta Modulator in 0.8-μm CMOS”, IEEE J. Solid-State Circuits, vol. 32, no. 6, pp. 783-796, June 1997:

$$FOM = \frac{4 {k}_{B} T \cdot {DR}^{2} \cdot BW}{Power} \qquad ( eq . 7 )$$

where k_{B} is the Boltzmann constant, DR is the dynamic range, BW is the bandwidth of the signal of interest (e.g. vibrations in the case of accelerometers) and power is the total power consumption of a device.

Experimental results show that the FOM for the example implementation is about 500.

The above described example embodiment provides a two-stage Capacitance-to-Voltage (CV) amplifier comprising an input stage, a class-AB output stage, a CMFB, an integrator capacitance feedback, a reference bias voltage circuitry used for the CMFB and a reset circuit. The above described example embodiment provides an amplifier whereby the stability requirements are not met for the unity gain configuration but can operate in a higher gain configuration in order to take into account parasitic capacitors due to a MEMS and ASIC packaging. The reset circuitry is designed so as not to configure the amplifier in a unity gain configuration during the CV amplifier reset phase. The bias current of the first input can also be reduced during the reset phase to fulfil the unity-gain stability requirement. The CMFB can provide a closed loop gain that is greater than one using both a resistive divider and a current gain divider, based on a current mirror ratio between the CMFB and the main differential amplifier (compare FIG. 6(a)) The reference bias voltage circuitry used by the CMFB can take into account the CMFB non-unity closed-loop gain and provide a desired common mode output voltage.

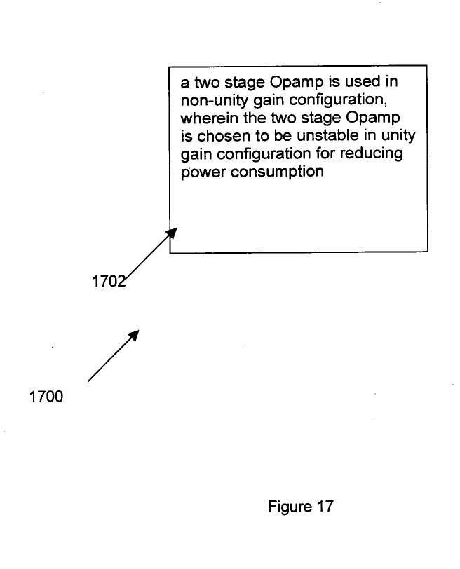

FIG. 17 is a schematic flowchart 1700 for illustrating a method for converting a sensor capacitance under parasitic capacitance conditions in an example embodiment. At step 1702, a two-stage op-amp is used in non-unity-gain configuration, wherein the two-stage op-amp is chosen to be unstable in unity-gain configuration for reducing power consumption.

The above example embodiments can achieve a high-resolution (e.g. 3.3 aF) converter circuit while consuming low-power e.g. 120 μW. The power consumption is significantly smaller than typical CV-converter designs. The example embodiment can achieve such low-power consumption because the example embodiment has a CV-converter architecture that can take into account the non-unity gain feedback circuitry including signals from the MEMS sensor. Further, the example embodiment can function using a low supply voltage e.g. 1.35V while typical CV-converters usually require 3V or 5V. Thus, the example embodiment is relatively more compatible for e.g. biomedical embedded systems. In addition, the example embodiment can provide a fully differential op-amp that functions in a non-unity-gain closed loop. Such architecture can be used in accelerometers and gyroscopes based on capacitive MEMS sensors.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

1. A method for converting a sensor capacitance under parasitic capacitance conditions, the method comprising the step of using a two stage operational amplifier (op-amp) in non-unity-gain configuration, wherein the two stage op-amp is chosen to be unstable in unity-gain configuration for reducing power consumption.

2. The method as claimed in claim 1, further comprising using a non-unity-gain reset circuit for performing offset cancellation operations.

3. The method as claimed in claim 1, wherein a reset is carried out by modifying a bias current intensity flowing in a first stage of the two stage op-amp.

4. The method as claimed in claim 1, further comprising using a common-mode feedback (CMFB) circuit for providing fully-differential operations.

5. The method as claimed in claim 4, wherein the CMFB circuit comprises a non-unity closed-loop gain.

6. The method as claimed in claim 5, wherein the non-unity closed-loop gain of the CMFB circuit is chosen based on a resistive divider and a current gain divider coupled to an output of the op-amp.

7. The method as claimed in claim 4, wherein another resistive voltage divider is used to provide a reference voltage to the CMFB circuit according to a chosen closed-loop gain.

8. A capacitance-to-voltage (CV) converter circuit for converting a sensor capacitance under parasitic capacitance conditions, the converter circuit comprising a two stage op-amp in non-unity-gain configuration, wherein the two stage op-amp is chosen to be unstable in unity-gain configuration for reducing power consumption.

9. The converter circuit as claimed in claim 8, further comprising a non-unity-gain reset circuit for performing offset cancellation operations.

10. The converter circuit as claimed in claim 9, wherein the non-unity reset circuit comprises at least two switches having different impedances such that activating the reset circuit generates a non-unity gain ratio across the converter circuit.

11. The converter circuit as claimed in claim 8, further comprising a reset circuit for modifying a bias current intensity flowing in a first stage of the two-stage op-amp.

12. The converter circuit as claimed in claim 11, wherein the reset circuit comprises a switch implemented in a biasing current branch of the first stage such that activating the switch modifies the biasing current intensity flowing in the first stage of the two-stage op-amp.

13. The converter circuit as claimed in claim 8, further comprising a CMFB circuit for providing fully-differential operations.

14. The converter circuit as claimed in claim 13, wherein the CMFB circuit comprises a non-unity closed-loop gain.

15. The converter circuit as claimed in claim 14, wherein the CMFB circuit non-unity closed-loop gain is chosen based on a resistive divider and a current gain divider coupled to an output of the op-amp.

16. The converter circuit as claimed in claim 13, wherein another resistive voltage divider is used to provide a reference voltage to the CMFB circuit according to a chosen closed-loop gain.
